(19) United States
(12) Patent Application Publication
(10) Pub. No.: US 2010/0246124 A1
(43) Pub. Date: Sep. 30, 2010

(54) Enclosure for Confining the Released Chemicals of Electrical Devices

(76) Inventor: Daniel STRONG, Mitchell, SD (US)

Correspondence Address: Muncy, Geissler, Olds & Lowe, PLLC, 4000 Legato Road, Suite 310, FAIRFAX, VA, 22033, US

(21) Appl. No.: 12/179,207

(22) Filed: Jul. 24, 2008

(51) Int. Cl. H05K 7/20; H05K 5/06

(52) U.S. Cl. 361/695; 174/50.5; 361/704

(57) ABSTRACT

An enclosure comprised of at least two members creates a sealable enclosed space. At least one of the members is a vessel that absorbs thermal energy from the enclosed space and transfers it into material it holds. Built into the enclosure is a connection means for connecting an enclosed device to outside devices. Disclosed is a moat based sealing configuration for a top and base enclosure. Also disclosed is an easily detachable heat transfer apparatus in which thermal energy transfer contact from an enclosed device to a housing member is formed as a housing portion is moved into closed position and concluded as the housing portion is moved away from closed position.

### BACKGROUND OF THE INVENTION

1. Field of the Invention

The present invention relates to housings for electrical devices and, more particularly, to tightly sealed enclosures for electrical devices to protect humans from the chemicals released by electrical devices.

2. Description of the Prior Art

Outgassing is a term referring to the release of a gas that was trapped, frozen, absorbed, or adsorbed in some material. In reference to indoor air quality, outgassing is sometimes referred to as offgassing. Household items that release chemicals into the air include plastic, plywood, particleboard, carpeting, vinyl flooring, adhesives, paints, fabrics, and much more. The rate of outgassing tends to correspond directly with the temperature of an item; the warmer its temperature, the more chemicals it releases into the environment.

Although wires, circuit boards, and plastic housings of modern devices are embedded with flame retardants to conform with current fire safety standards, some widely used flame retardants are suspected of posing health risks. Certain types of brominated flame retardants (BFRs) have been banned in Europe while remaining legal in America. Older devices also contain dangerous chemicals including heavy metals and polychlorinated biphenyls (PCBs) and can continue to release chemicals into the air over their entire life span.

The Electronics Take Back Coalition, formerly known as the Computer Take Back Campaign, states that flame retardants used in electrical devices are suspected of being endocrine disruptors, immunotoxins, and neurotoxins. This is especially worrisome because, as a device's components warm up, flame retardants are outgassed into the surrounding environment and can be inhaled by people. A 2004 study conducted by the coalition found that flame retardants suspected of causing health problems are showing up in blood samples around the world. The same group also found that women in North America have the highest levels of flame retardants in their breast milk of those sampled.

Some electrical devices, although small in size, release a large amount of chemicals into the air. For example, the plastic housing of a computer modem, which is embedded with flame retardants, is continually heated by internal components. Computer modems usually do not have an off button. Therefore, unless they are unplugged, they are always releasing chemicals into the air.

Such chemicals are especially troublesome to some people. The inventor of the present invention has at various times experienced unpleasant symptoms including headaches, abdominal pain, sleeplessness, worsened mood, worsened cardio-vascular function, increased dental plaque, loss of mental clarity, loss of visual acuity, vague feelings of physical discomfort, enervation, and depression, among other symptoms. These symptoms are set off by using TVs, kitchen blenders, computers, computer modems, computer monitors, stereos, and other electrical devices for prolonged periods of time.

In an effort to rule out a suspected cause of these negative symptoms, the inventor constructed a tightly sealed enclosure for his computer's modem from aluminum foil, duct tape, and school glue. The use of this enclosure resulted in a noticeable decrease in symptoms. Additionally, the inventor has repeatedly found that maintaining a flow of outdoor air through the environment surrounding the computer increases the length of exposure time which can be tolerated before negative physical symptoms are experienced. This, too, supports the conclusion that released chemicals are the cause of his negative symptoms and that an enclosure could be used to protect himself and others like himself.

An electrical device's heat must be dissipated or the device can sustain damage. The typical heat management scheme requires that air go through the device. The exiting air brings with it the device's waste heat and chemicals released by the device. When fans are necessary to move the air, they are often found to be too noisy for workplace and home environments.

Within an enclosure for an electrical device, sometimes convection can effectively be used to transfer heat from the device to the enclosure and from the enclosure to the external environment. However, the enclosure must be thick enough to prevent hot spots and uneven heat distribution, whereas enclosures are usually thin in order to achieve a reasonable weight. If the thermal absorption potential of the enclosure could be increased by adding material to the enclosure, and if heat could be transferred across a larger portion of the enclosure, the thermal absorption ability and thermal management ability of the enclosure would be improved without greatly increasing the enclosure's weight. Water could be used for such a purpose. If combined with a fan, water might also offer the possibility of evaporative cooling. If a portion of the enclosure was surrounded by and in contact with fan cooled water, an enclosed device's waste heat would be absorbed much faster. Despite the benefits which might be realized, the inventor is unaware of any enclosure for electrical devices using water in this way.

Heat transfer apparatuses, such as heat pipes and conductive heat transfer assemblies, can effectively transfer heat from an enclosed device directly to portions of the enclosure, but their use can pose an inconvenience. A heat transfer apparatus must be detached from the device before the device can be removed from an enclosure or housing. Also, thermal bonding gel must be reapplied every time the heat transfer apparatus is re-attached.

In addition, the liquescent synthetic filler materials used to seal enclosures usually release undesirable odors and undesired chemicals into the air. Furthermore, such sealant materials cannot be reused. Wax, on the other hand, can be melted and thus reused repeatedly without losing its effectiveness and does not outgas undesired chemicals. Wax might prove an ideal sealing material. However, enclosures for electrical devices heretofore have not been designed to be sealed with wax.

Enclosures for electrical devices often have doors to give access to enclosed devices, but door seals have problems. It is difficult to create an airtight seal. In addition, over time, as the door is repeatedly opened and closed, the seal may be weakened, gradually losing its effectiveness. Door seals themselves are, moreover, made from chemicals that outgas and have bad odors. A two-part enclosure consisting of a top and a base offers advantages over an enclosure with a door, advantages which seem to have been unappreciated thus far. A moat could be included on the base, and the hem of the top could fit into the base's moat. Wax could be poured into the moat to seal the enclosure. In this type of enclosure, there would be no seal degradation problems because wax can be melted and reformed.

In such a two-part clam-shell type enclosure in which the enclosed device is sitting on the base, it would be useful to transfer heat from the enclosed device directly to the top enclosure member. However, in such an arrangement, connecting the enclosed device to the top enclosure member presents a challenge. For the heat transfer apparatus to be attached to both the enclosed device and the top enclosure member, the top must be resting on the base in normal operating position. However, the normal operating position is the closed position. Thus, there is no way to access the enclosed space for the purpose of attaching the heat transfer apparatus. It would be ideal if heat transfer contact between the enclosed device and the top enclosure member could be initiated as the top is lowered onto the base and severed as the top is lifted from the base. Unfortunately, to the best of the inventor's knowledge, no such heat transfer configuration for an electrical device enclosure currently exists.

Enclosures have previously been made primarily to protect the enclosed device from the outside world, rather than protecting the outside world from the device. Companies making computer enclosures include Electrorack Enclosure Products of Anaheim, Calif.; PC Enclosures of Lehighton, Pa.; Envirosafe Technologies Inc. of Jacksonville, Fla.; GizMac Accessories of Torrance, Calif.; ITS Enclosures of Mt. Pleasant, Pa.; Aitech Defense Systems, Inc. of Oakland, Calif.; and Armagard of Birmingham, United Kingdom. Most of the enclosures offered by these companies do not confine the released chemicals, but release them into the outside environment. The rest of the enclosures are too noisy, bulky, or have cooling systems that are too expensive.

Inventions have been made to protect users from electrical radiation, but these inventions do not protect users from released chemicals.

Likewise, patented enclosures for electrical devices do not offer an acceptable solution. U.S. Pat. No. 7,165,413 to Symons, 2007, is an integrated liquid cooling device with immersed electronic components. Immersing devices in liquid is not a practical way to enclose most devices. U.S. Pat. No. 6,170,562 to Knoblauch, 2001, is a device for the exchange of thermal energy between the interior of a housing and the exterior. It relies too heavily on the use of fans or pumps. It would be too noisy. U.S. Pat. No. 4,589,712 to Hastings, 1978, is an enclosure for data processing equipment. It is overly complicated. U.S. Pat. No. 3,997,819 to Eggert et. al., 1976, is a housing for electrical communications and measuring devices. It is not practical for most existing devices.

### SUMMARY OF THE INVENTION

Accordingly, the objects and advantages of the present invention are:

(a) to significantly reduce a human's exposure to an enclosed electrical device's released chemicals;
(b) to have an increasable thermal absorption ability and to spread heat evenly;
(c) to have a simple, low cost, and quiet cooling system and more specifically to provide water based evaporative cooling or totally silent cooling;
(d) to provide reasonably easy access to an enclosed device without requiring a door;
(e) to be easily sealed with wax;
(f) to accommodate existing devices of varying sizes;
(g) to be practical for home or workplace use;
(h) to provide easily detachable and easily re-attachable conductive heat transfer; and
(i) to provide conductive heat transfer in which heat transfer contact from an enclosed device to an enclosure member is formed as the enclosure is closed and concluded as a the enclosure is opened.

To achieve the above objects, the present invention provides an enclosure for confining an electrical device and its released chemicals. The enclosure is comprised of a plurality of members. The enclosure's members define within their union at least one sealable enclosed space for enclosing an electrical device. At least one of the enclosure's members is a vessel. When the vessel is filled with material, the material absorbs thermal energy from the enclosed space and spreads heat evenly over a larger area. Also included is at least one means for connecting an enclosed electrical device to an external power source or device.

Alternately, the members include at least a base member and at least a top member. The base member comprises a moat, into which a sealant material such as wax can be deposited. The top member comprises a hem that fits into the base member's moat. Also included is a means for connecting an enclosed electrical device to an external power source or device.

Moreover, the present invention also provides a heat transfer apparatus for a housed electrical device. The apparatus includes a housing portion and a displaceable heat conductive mass. As the housing portion is closed, the displaceable heat conductive mass is contacted and thermal energy flows from a housed electrical device to the housing portion. As the housing portion is opened, contact is concluded. Thereby, the electrical device transfers heat directly to its housing and is easily detached from its housing as well.

Still further objects and advantages will become apparent from a consideration of the ensuing description and drawings.

### BRIEF DESCRIPTION OF THE DRAWINGS

FIG. 1A shows a perspective view of a preferred embodiment of the present invention.

FIG. 1B shows a front sectional view of the preferred embodiment of the present invention.

FIG. 1C shows a side sectional view of the preferred embodiment of the present invention.

FIG. 1D shows a rear sectional view of the preferred embodiment of the present invention.

FIG. 1E is a schematic view showing the base's sealant receptacle of the preferred embodiment of the present invention.

FIG. 1F is a schematic view showing the DVD compartment of the preferred embodiment of the present invention.

FIG. 1G shows a right side view of the preferred embodiment of the present invention.

FIG. 1H is a schematic view showing the displaceable heat conductive material and the protrusion prior to contact of the preferred embodiment of the present invention.

FIG. 1I is a schematic view showing the displaceable heat conductive material and the protrusion during contact of the preferred embodiment of the present invention.

### REFERENCE NUMERALS

1 material (water)
2 vessel
4 enclosed space
5 base
7 wax
8 glass
9 base's bottom surface
10 moat
11 base's perimeter wall
12 drain
13 drain valve
15 gap between perimeter wall and sealant receptacle
20 video screen
21 chassis for video screen and motherboard
22 motherboard
23 CPU
24 hard disc drive
25 power supply
26 absorber
30 vessel's hem
36 extruded heat sink fins
40 sealant receptacle (perimeter wall)
41 power button
42 reset button
43 video screen buttons
50 dvd drive
51 dvd compartment
52 sealant receptacle (DVD compartment)
60 heat transfer apparatus constituents
61 displaceable heat conductive material (mineral oil)
62 protrusion
63 cup
64 cup chassis
67 integument
68 screw
70 dust cover
71 dust cover's downward recession
72 dust cover's perimeter edges
73 dust cover's water
74 dust cover's extension
80 fan
   90 cable

### DETAILED DESCRIPTION OF THE PREFERRED EMBODIMENT

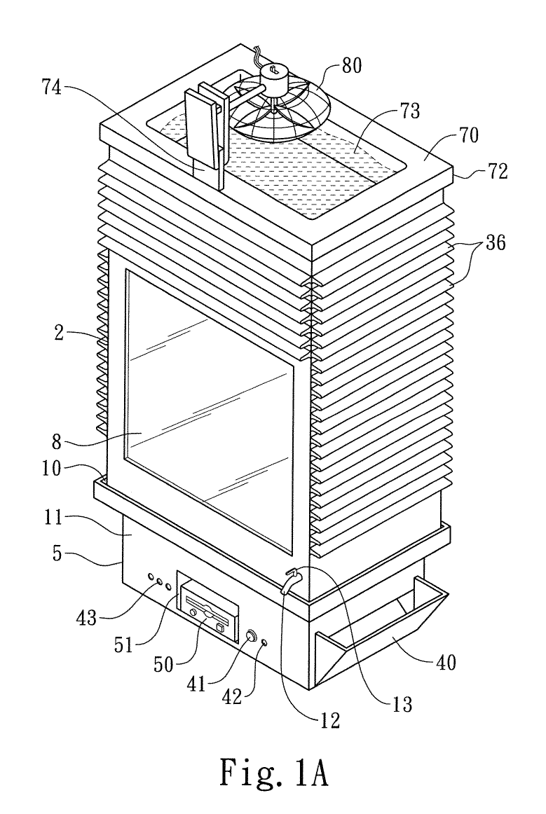

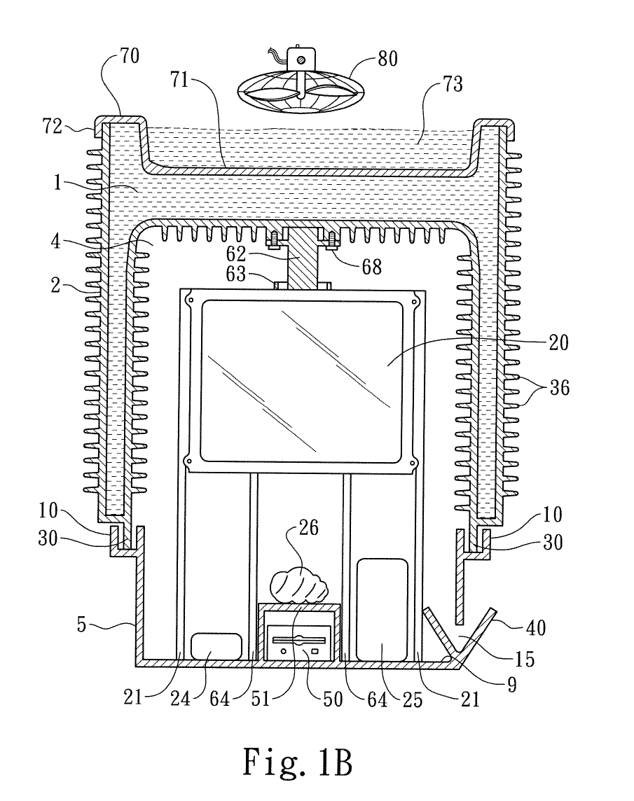

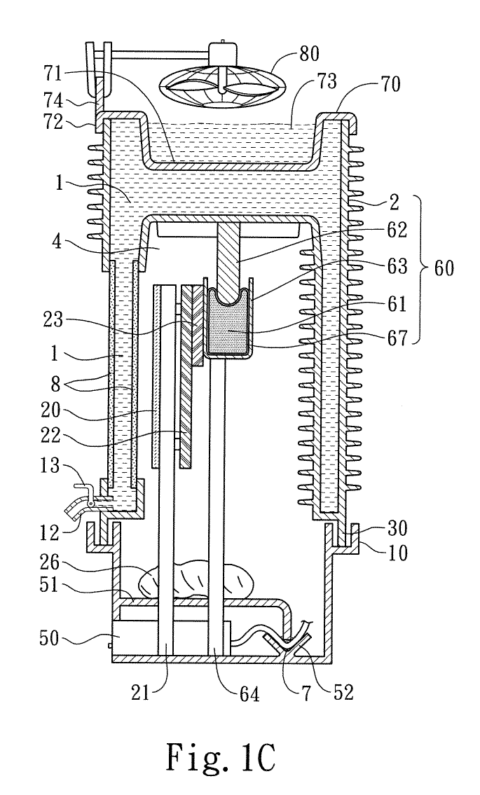

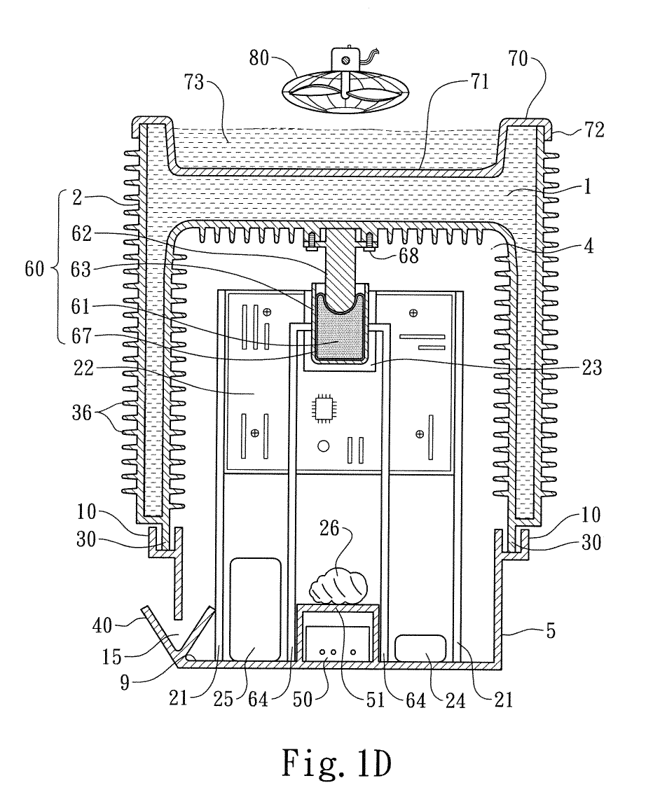

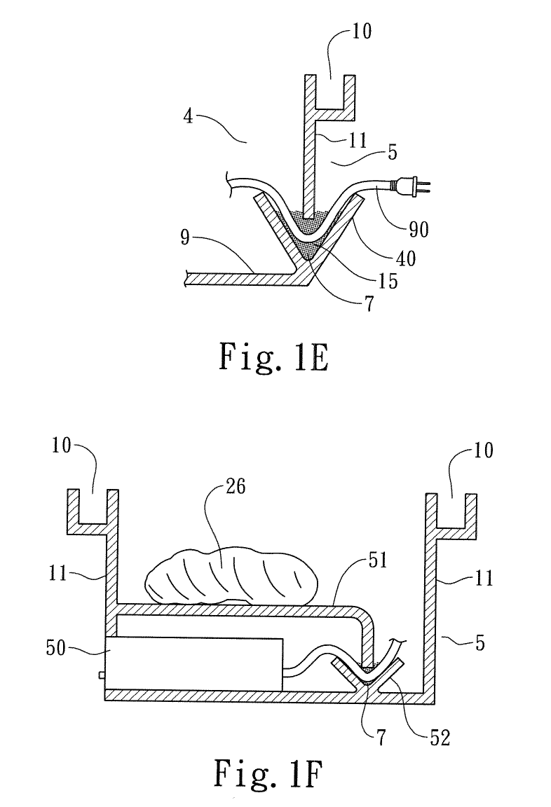

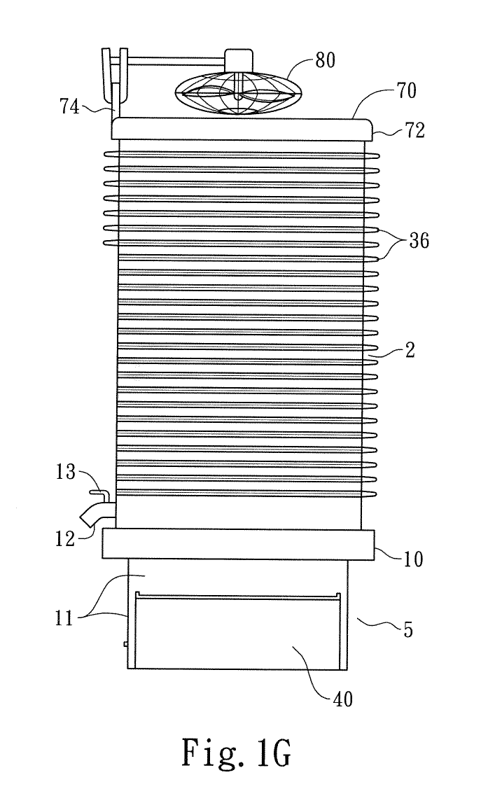

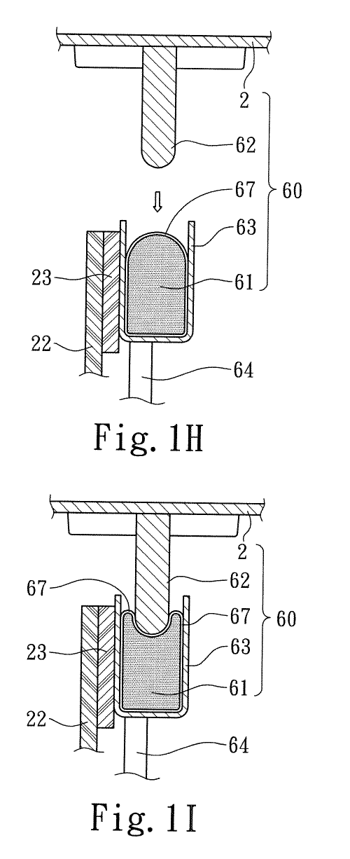

A preferred embodiment of the present invention is shown in FIGS. 1A-1I. As shown in FIG. 1A, it is an enclosure for a personal computer. It has two members. It has a top member 2 and a bottom member 5. Both members are made from aluminum. Aluminum is the preferred material due to its good thermal conductivity and its resistance to water corrosion. Other heat conductive and water resistant materials could be used, such as copper or ceramic.

As shown in FIG. 1B, lining most of the top member 2 are fins 36. The fins 36 improve the thermal absorption and dissipation of the enclosure. The fins 36 face inward in the enclosed space 4 and outward on the outside.

The top member 2, which can hold material, is hereinafter referred to as the vessel. The bottom member 5 on which electrical devices are secured or placed is hereinafter referred to as the base.

As shown in FIG. 1A, the base 5 is rectangular and trough shaped. The base 5 has a perimeter wall 11 around its perimeter. There is a moat 10 around the top of the perimeter wall 11. As shown in FIG. 1B, the vessel has an edging, downward facing rim, or hem 30 along its bottom. When the members are assembled or in the closed position, the vessel's hem 30 sits in the base's moat 10.

As shown in FIG. 1E, a sealant receptacle 40 is built into the base 5. The sealant receptacle 40 is accessible from both in the enclosed space 4 and outside of the enclosure. The base's perimeter wall 11 extends into the sealant receptacle 40. There is a gap 15 between the base's perimeter wall 11 and the sealant receptacle 40. The gap 15 allows the enclosed devices' cables to pass through. After one or more of the cables 90 are passed through, the enclosure can be sealed by pouring wax 7 into the sealant receptacle 40.

As shown in FIG. 1B, included in this embodiment is a video screen 20. As shown in FIG. 1D, also included is a motherboard 22. As shown in FIG. 1C, the motherboard 22 is directly behind the video screen 20.

As shown in FIGS. 1B-1D, also included are a DVD drive 50, DVD compartment 51, hard disc drive 24, power supply 25, and absorber 26. The enclosed devices are connected to each other as in a normal computer. The internal connecting wires have been omitted from the drawings for the sake of simplicity. The video screen 20 and the motherboard 22 are supported by and secured to a support chassis 21. The chassis 21 is secured to the base 5. The absorber 26 rests on the DVD compartment 51. The absorber 26 is preferably a fine-mesh bag filled with activated carbon. It is meant to absorb the enclosed devices' released chemicals and reduce their accumulation within the enclosed space 4. The hard disc drive 24 and the power supply 25 rest on the base's bottom surface 9.

As shown in FIGS. 1B-1D, the vessel 2 is filled with material 1. The vessel walls lining the enclosed space 4, act as a thermal interface between the material 1 the vessel holds and the enclosed space 4. In this embodiment, the material chosen to fill the vessel 2 is water 1. Water 1 is preferred because, in addition to being heat conductive, it is readily available and it is transparent allowing the video screen 20 to be viewed. The vessel 2 forms an upside down sink shaped cavity for holding material. The vessel's water 1 extends down along all four vertical sides of the enclosed space 4. Having the water 1 extend down in this way limits hot spots in the enclosure and allows heat to evenly spread out and be dissipated from a larger area. It also greatly increases the thermal absorption ability of the enclosure.

As shown in FIG. 1C, the water 1 extends down in the front of the vessel between two panes of glass 8. This allows the user to view the video screen 20. It also allows heat to pass through the water and escape through the glass. Preferably the glass is high-strength, fracture-resistant glass to protect the sensitive enclosed devices. The glass pieces are sealed to the aluminum with an adhesive. Many types of adhesives could be used; a silicon adhesive would be effective, for example.

As shown in FIGS. 1C and 1D, this embodiment also has a heat transfer apparatus 60. The heat transfer apparatus 60 forms a thermal interface between the housed or enclosed CPU 22 and an enclosure-member/housing-portion 2. The heat transfer apparatus's constituents 60 include a displaceable heat conductive material 61 and a housing portion 2. The housing portion in this embodiment is the vessel 2. The vessel 2 is also the top enclosure member. Also included with the heat transfer apparatus 60 is a protrusion 62. As shown in FIG. 1D, the protrusion 62 is attached to the vessel 2 with screws 68 and is thermally bonded to the vessel 2. The protrusion 62 extends down from the top of the enclosed space 4. Liquids, gels, or even compressible solids could be used as the displaceable heat conductive material 61. In addition to being displaceable, the selected material should transfer heat well. In this embodiment, the displaceable heat conductive material 61 is mineral oil 61. Mineral oil 61 is preferred because, unlike water, it is not harmful to most electrical components.

As shown in FIGS. 1H-H, the displaceable heat conductive material 61 is encased in an integument 67. Together, the displaceable heat conductive material 61 and its integument 67 make up a displaceable heat conductive mass. The integument 67 is comprised of solid material and prevents the displaceable heat conductive material 61 from spilling. The integument 67 is preferably heat conductive and pliable. A heat conductive rubber could be used to make the integument 67.

A cup 63 for holding the displaceable heat conductive material 61 and its integument 67 is thermally bonded to the CPU 23. The cup 63 is thermally conductive and made from aluminum. The cup 63 contacts the integument 67, transferring heat through the integument 67 to the displaceable heat conductive material 61. The cup 63 is held steady by and attached to its own aluminum chassis 64.

As shown in FIGS. 1H-1I, as the top member or vessel 2 is lowered onto the base 5, the protrusion 62 comes into contact with the integument 67. When the vessel 2 is resting on the base, the protrusion 62 extends down from the top of the enclosed space 4 contacting the integument 67 enabling conductive heat transfer from the CPU 23 to the vessel 2 and from the vessel 2 to the vessel's material (water) 1. In situations where no integument is necessary, the protrusion or a housing-portion/enclosure-member itself could contact the displaceable heat conductive material directly.

As shown in FIG. 1D, in this embodiment the protrusion 62 is a separate structure from the enclosure. Alternately, the vessel 2 could be shaped to form a protrusion. For example, a protrusion could be a downward water filled extension of the vessel 2.

As shown in FIG. 1F, there is a DVD compartment 51 built into the base 5. The DVD compartment 51 allows the DVD drive 50 to be accessed from the outside like a normal DVD drive. The DVD drive 50 sits in the DVD compartment 51. Alternately, the DVD drive 50 could be fastened in place. The DVD drive 50 is a normal DVD drive. It is not sealed. DVD drives are typically not used frequently and are not major outgassers. However, the DVD drive could itself be sealed or could be accessible through a sealed door. The DVD compartment 51 has a sealant receptacle 52 similar to the base's previously discussed sealant receptacle 40. The DVD compartment's sealant receptacle 52 allows the DVD drive 50 to be connected to the motherboard 22 while maintaining the enclosure's seal. Like the base's sealant receptacle 40, the DVD compartment's sealant receptacle 52 is sealed with wax 7.

As shown in FIG. 1D, there is an aluminum dust cover 70 sitting on the vessel 2. Its perimeter edges 72 bend down fitting outside the vessel's upper portion. It keeps dust out of the vessel's water 1. It limits evaporation of the vessel's water 1. It is downward recessed. Its downward recession 71 makes contact with the vessel's water 1. Its downward recession 71 also holds water 73. Its water 73 is exposed to the outside environment and can be blown on with the included fan 80.

As shown in FIG. 1A, included with this embodiment is a fan 80. The fan 80 preferably includes an extremely quiet setting. The fan 80 blows on the exposed surface of the dust cover's water 73. The fan 80 is mounted on the dust cover's extension 74. It is turned on manually by the user.

As shown in FIG. 1G, there is a drain 12. It is located in the front, near the bottom of the vessel 2. The drain has a valve 13.

### Operation

As shown in FIGS. 1E-F, to connect an enclosed device to an outside power source or an outside device, or to connect the DVD drive 50 to the motherboard 22, the appropriate cables are extended through the sealant receptacles 40 and 52. The sealant receptacles 40 and 52 are filled with wax 7.

In a similar way, wax is poured into the base's moat 10, filling the moat about halfway. As the enclosure is assembled, the vessel's hem 30 is lowered into the moat 10 and submerges in the wax.

As shown in FIGS. 1H-I, as the vessel 2 comes down to rest on the base, the protrusion 62 contacts the integument 67 enabling conductive heat transfer. As the vessel 2 is lifted from the base 5, contact is concluded.

The moat's wax, used to seal the enclosure, should be melted prior to lifting the vessel 2 from the base 5. The sealant receptacles' waxes 7 should be melted prior to removing an enclosed device's cables. The moat's and sealant receptacles' waxes are melted by applying a heat source. Many different types of heat sources could be used. A blow dryer could be used effectively. To make the vessel 2 easier to lift, the drain's valve 13 is turned, allowing the water to be drained. After the water has drained, the vessel 2 can be more easily lifted off

Objects can be placed in the dust cover's water 73. In this way, cold packs from a refrigerator or freezer can silently and powerfully cool the enclosure. When using cold packs, it is not necessary to use the fan 80. Thus, the enclosure is capable of being totally silent, while also maintaining a lower temperature in the vessel's water 1.

The above described enclosure provides many useful and unique features. However, while the description above contains many specific details, these should not be construed as limitations on the scope of the invention's application, but rather as one implementation of the concepts developed here. Many other variations are possible.

For example, to give easier access to enclosed devices, an enclosure could have one or more doors. The doors could have inflatable seals. To compensate for any leaks in the doors, a large absorber could be used. A burp valve could be included to release pressure from the enclosed space as it initially warms up. The enclosure could have a rounded shape both internally and externally. A cut off switch could turn off the enclosed devices if they become too hot.

The enclosure's members could be one vessel and one door or several vessels and several doors. The enclosure could have one base with several moats and a top for each moat, forming several separate enclosed spaces. The enclosure could be larger or smaller depending on the intended device. Enclosed devices could be attached to or hang from any of the members.

Instead of sealant receptacles, airtight connectors could be used. The enclosure's surfaces could be entirely flat with no fins. The enclosure's fan could be thermostatically controlled. The enclosure could have multiple fans or no fans. A fan could be placed inside the enclosed space.

The heat transfer apparatus could include a phase-change device such as a heat pipe, thermosiphon, or other similar device. A pump could be used to circulate the material held by the vessel. The displaceable heat conductive material could sit directly on a heat producing element with or without an integument and with our without a cup. The housing-portion/enclosure-member could contact the integument directly with no protrusion.

The protrusion could be comprised of a flexible fluid filled fabric tube wherein the fabric does not leak and is either heat conductive or has a heat conductive portion. The enclosure could have several protrusions for multiple devices. The displaceable heat conductive material could be a compressible mass of solid material such as heat conductive silicone rubber. It would therefore require no additional covering to prevent spills.

The displaceable heat conductive material could be attached to the housing portion and the protrusion could be attached to the device.

The vessel could be filled with a material other than water. For example, it could be filled with gel, oil or another suitable material. The material the vessel holds could lie next to a smaller portion of the enclosed space. For example, it could lie next to just a portion of one side of the enclosed space.

An air pressure valve and gauge could be built into the enclosure to maintain a pressure differential and let the user be confident of the seal's condition.

Furthermore, it is worth noting that although this enclosure is intended to be used to protect the outside world from an enclosed device, it might also prove useful for protecting devices from the outside world.

Accordingly, the scope of the invention should be determined not by the embodiment illustrated, but by the appended claims and their legal equivalents.

What is claimed is:

1. An enclosure for at least one electrical device comprising:
(a) a plurality of members defining within their union at least one sealable enclosed space, and
(b) at least one connection means for connecting an enclosed electrical device to an external power source or device,
wherein at least one of said members is a vessel, and when said vessel is filled with material at least a portion of said vessel is a thermal interface between said enclosed space and said material, whereby said housing portion's thermal absorption potential is increasable by adding material to said vessel.

2. The enclosure as claimed in claim 1, wherein the connection means comprises:
(a) at least one sealant receptacle that is accessible from both in said enclosed space and outside of said enclosure,
(b) at least one wall of at least one of said members extending into said sealant receptacle, and
(c) at least one gap between said wall and said sealant receptacle, whereby an enclosed device's cables pass through said sealant receptacle to the outside.

3. The enclosure as claimed in claim 1 further comprising at least one heat transfer apparatus.

4. The heat transfer apparatus of claim 3, further comprising at least one displaceable heat conductive material.

5. The heat transfer apparatus of claim 3, further comprising at least one protrusion.

6. The heat transfer apparatus of claim 4, further comprising an integument for said displaceable heat conductive material, whereby said displaceable heat conductive material is prevented from spilling.

7. The enclosure as claimed in claim 1, further comprising a dust cover for said vessel, wherein
(a) said dust cover is also a water container,
(b) said dust cover makes contact with vessel's said material provided said vessel is filled sufficiently high, and
(c) when said dust cover is filled with water said dust cover has an exposed water surface,
whereby said dust cover receives thermal energy from said enclosed space.

8. The enclosure as claimed in claim 1, further comprising at least one exposed water surface and at least one fan disposed to blow on said exposed water surface.

9. The enclosure as claimed in claim 1, wherein at least one of said members comprises a moat, and at least one other of said members comprises a hem that fits into said moat, whereby said enclosure is easily sealable.

10. An enclosure for an electrical device, comprising:
(a) a plurality of members defining within their union at least one sealable enclosed space for enclosing an electrical device, wherein said members include at least one base member and at least one top member, wherein said base member comprises at least one moat and a said top member comprises at least one hem that fits into said moat, and
(b) at least one connection means for connecting an enclosed device to an outside power source or device,
whereby said enclosure can be opened without the disadvantages involved with having a door and can be easily sealed.

11. The enclosure as claimed in claim 10, wherein said connection means further comprises:
(a) a sealant receptacle that is accessible from both in said enclosed space and outside of said enclosure,
(b) at least one wall of at least one of said members extending into said sealant receptacle, and
(c) at least one gap between said wall and said sealant receptacle,
whereby an enclosed device's cables can pass through said sealant receptacle to the outside.

12. The enclosure as claimed in claim 10 further comprising at least one heat transfer apparatus.

13. The heat transfer apparatus of claim 12, comprising at least one displaceable heat conductive material.

14. The heat transfer apparatus of claim 12, further comprising at least one protrusion.

15. The heat transfer apparatus of claim 13, further comprising an integument for said displaceable heat conductive material, whereby spills are prevented.

16. A heat transfer apparatus comprising:
(a) at least one electrical device,
(b) at least one housing portion, and
(c) at least one displaceable heat conductive mass,
wherein
(a) when said housing portion is in a closed position said displaceable heat conductive mass is a thermal interface between said housing portion and said electrical device,
(b) said displaceable heat conductive mass is contacted by at least one other heat transfer apparatus constituent as said housing portion is moved toward a closed position, and
(c) said displaceable heat conductive mass concludes contact with said other heat transfer apparatus constituent as said housing portion is moved away from said closed position,
whereby thermal energy transfer between said electrical device and said housing portion is easily established and said electrical device is easily detached from said housing portion.

17. The heat transfer apparatus of claim 16, further comprising at least one protrusion.

18. The heat transfer apparatus of claim 16, wherein said housing portion is also a vessel wherein when said vessel is filled with material at least a portion of said vessel is an interface between said enclosed space and said material, whereby said vessel's thermal absorption ability is increasable by adding material to said vessel.

19. The heat transfer apparatus of claim 18, further comprising an exposed water surface and a fan, wherein said fan is disposed to blow on said water.

20. The heat transfer apparatus from claim 18, further comprising a dust cover, wherein
(a) said dust cover is also a water container,
(b) said dust cover makes contact with housing portion's said material provided said housing portion is filled sufficiently high, and
(c) when said dust cover is filled with water said dust cover has an exposed water surface,
whereby said dust cover receives thermal energy from said enclosed space.
